(19) United States
(12) Patent Application Publication
(10) Pub. No.: US 2026/0313923 A1
(43) Pub. Date: Oct. 8, 2026

(54) CAPACITOR, METHOD OF MANUFACTURING CAPACITOR, AND METHOD OF MANUFACTURING MEMORY DEVICE

(71) Applicant: EGTM Co., Ltd., Suwon-si (KR)

(72) Inventors: Kyu Ho CHO, Suwon-si (KR); Ju Hwan JEONG, Suwon-si (KR); Hyeon Sik CHO, Suwon-si (KR); Ha Na KIM, Suwon-si (KR); Jae Min KIM, Suwon-si (KR); Duck Hyeon SEO, Suwon-si (KR); Shin Beom KIM, Suwon-si (KR)

(73) Assignee: EGTM Co., Ltd., Suwon-si (KR)

(21) Appl. No.: 19/630,237

(22) Filed: Mar. 26, 2026

(30) Foreign Application Priority Data
Apr. 2, 2025 (KR) 10-2025-0043162

(51) Int. Cl. H10D 1/68; H10B 12/00; H10D 1/00

(52) U.S. Cl. CPC H10D 1/696; H10B 12/03; H10D 1/043; H10D 1/714

(57) ABSTRACT

A method of manufacturing a capacitor comprises forming a lower electrode having first, second, and third electrode layers and a supporter supporting the lower electrode; removing the first electrode layer located on a sidewall of the lower electrode; forming a dielectric film on an outer surface of the lower electrode; and forming an upper electrode on the dielectric film.

### CROSS-REFERENCE TO RELATED APPLICATION

This application claims priority to and the benefit of Korean Patent Application No. 10-2025-0043162, filed on Apr. 2, 2025, the disclosure of which is incorporated herein by reference in its entirety.

### BACKGROUND

### TECHNICAL FIELD

The present invention relates to a capacitor, a method of manufacturing the same, and a method of manufacturing a memory device, and more particularly, to a capacitor in which a portion of a lower electrode is selectively removed and a metal oxide having a high work function is formed, and a method of manufacturing such a capacitor and a method of manufacturing a memory device.

### RELATED ART

Currently, capacitors in DRAM devices are the subject of continuous research on MIM (Metal/Insulator/Metal) capacitors using metal electrodes. Titanium nitride film (TiN), which has low resistivity and high stability, is currently widely used as an electrode material.

As semiconductor devices continue to be integrated, the size of capacitors for semiconductor devices continues to decrease. Various studies are being conducted to increase the capacitance of dielectric films such as HfO2 and ZrO2 in a limited space. To facilitate crystallization of the dielectric film, a method of using a high work function material such as Nb2O5 as a seed layer has been proposed.

Through this approach, a crystal structure having a high dielectric constant can be formed even at relatively low temperatures. However, there is a problem that the seed layer is deposited not only where it should be deposited but also on the supporter (silicon nitride, SiN), causing leakage current. Therefore, selective deposition is required.

Recently, another method has been proposed to increase the crystallization of the dielectric film by changing the TiN electrode to a high work function material such as NbN, TaN, or MoN. While these materials are high work function materials that facilitate crystallization of the dielectric film, they have high resistivity, and when deposited directly on a contact plug (W, tungsten), contact resistance increases. Therefore, they cannot be used alone and are used as a composite electrode of TiN/NbN/TiN.

When depositing a TiN/NbN/TiN composite electrode, Nb is diffused into the lower electrode TiN through heat treatment, forming a doped TiN film, which has the effect of increasing crystallization as if Nb2O5 were deposited. However, compared to directly depositing Nb2O5 on the TiN electrode, the effect is less, and to further increase the dielectric constant, a process capable of selectively depositing Nb2O5 only on the TiN electrode is required.

### SUMMARY

An object of the present invention is to provide a method of manufacturing a capacitor and a method of manufacturing a memory device capable of improving characteristics of a thin film.

Other objects of the present invention will become more apparent from the following detailed description.

According to an embodiment of the present invention, a method of manufacturing a capacitor comprises: forming a lower electrode positioned on a contact plug and a supporter supporting an outer wall of the lower electrode, the lower electrode having a first electrode layer, a second electrode layer formed inside the first electrode layer, and a third electrode layer formed inside the second electrode layer; removing the first electrode layer located on an exposed sidewall of the lower electrode; forming a dielectric film on the outer surface of the lower electrode; and forming an upper electrode on the dielectric film.

The first and third electrode layers may include at least one of a tetravalent metal nitride film including TiN, a pentavalent metal nitride film including NbN and TaN, a hexavalent metal nitride film including MoN and WN, and a tetravalent semi-metal nitride film including SiN and TiSiN.

The second electrode layer may have a higher work function than the first electrode layer.

The second electrode layer may include at least one of a tetravalent metal nitride film including TiN, a pentavalent metal nitride film including NbN and TaN, and a hexavalent metal nitride film including MoN and WN.

The step of removing the first electrode layer may be a wet cleaning etch, a dry cleaning etch, or an ALE (Atomic Layer Etch) process.

The step of removing the first electrode layer may comprise removing the first electrode layer on the outer wall of the lower electrode to expose the second electrode layer, and leaving the first electrode layer inside the supporter and adjacent to the contact plug.

The dielectric film may include at least one of a trivalent metal oxide film including Al2O3, a tetravalent metal oxide film including ZrO2 and HfO2, a pentavalent metal oxide film including Ta2O5, or a combination thereof.

The step of forming the dielectric film may comprise oxidizing the second electrode layer located on the exposed sidewall of the lower electrode to form an interfacial layer.

The step of removing the first electrode layer may comprise oxidizing the second electrode layer located on the exposed sidewall of the lower electrode to form an interfacial layer.

The step of forming the interfacial layer may comprise leaving the second electrode layer located inside the supporter and on top of the contact plug.

The interfacial layer may include at least one of titanium oxide (TiOx), niobium oxide (NbOx), tantalum oxide (TaOx), molybdenum oxide (MoOx), and tungsten oxide (WOx).

According to an embodiment of the present invention, a method of manufacturing a memory device may comprise the above-described method of manufacturing a capacitor.

According to an embodiment of the present invention, a capacitor comprises: a contact plug on a substrate; a lower electrode on the contact plug; a supporter supporting an outer wall of the lower electrode; a dielectric layer on the lower electrode; an upper electrode on the dielectric layer; and an interfacial layer between the lower electrode and the dielectric layer, wherein the lower electrode has first to third electrode layers sequentially stacked within the supporter and above the contact plug.

The lower electrode may further have second and third electrode layers sequentially stacked on the outer wall within the interfacial layer.

According to an embodiment of the present invention, the capacitor can form a dielectric film having a high dielectric constant, thereby enabling formation of a high-k thin film. Furthermore, the overall capacitor manufacturing process can be shortened, and the performance and manufacturing yield of semiconductor devices can be improved.

### BRIEF DESCRIPTION OF DRAWINGS

FIG. 1 is a cross-sectional view schematically showing a capacitor according to an embodiment of the present invention.

FIGS. 2A and 2B are views schematically showing a method of manufacturing a capacitor according to Comparative Example 1.

FIGS. 3A and 3B are views schematically showing a method of manufacturing a capacitor according to Comparative Example 2.

FIGS. 4A to 4C are views schematically showing a method of manufacturing a capacitor according to Comparative Example 3.

FIGS. 5A to 5E are views schematically showing a method of manufacturing a capacitor according to an embodiment of the present invention.

### DESCRIPTION OF EXAMPLE EMBODIMENTS

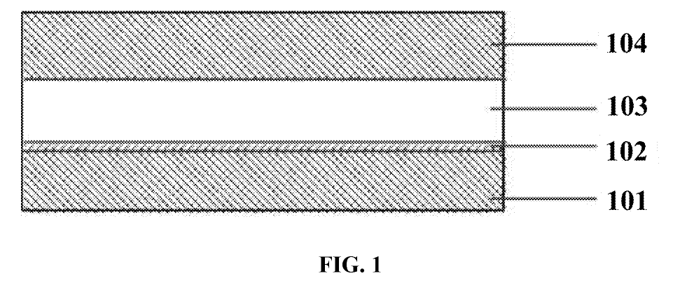

Hereinafter, preferred embodiments of the present invention will be described in more detail with reference to the accompanying FIGS. 1 to 5E. The embodiments of the present invention may be modified in various ways, and the scope of the present invention should not be construed as being limited to the embodiments described below. The embodiments are provided to explain the present invention in more detail to those having ordinary knowledge in the technical field to which the present invention belongs. Therefore, the shape of each element shown in the drawings may be exaggerated to emphasize a clearer explanation.

FIG. 1 is a cross-sectional view schematically showing a capacitor according to an embodiment of the present invention. As shown in FIG. 1, the capacitor may include a lower electrode 101, an interfacial layer 102, a dielectric layer 103, and an upper electrode 104.

The lower electrode 101 may include silicon, a metal, a metal compound, or a combination thereof. The metal compound may include a metal, a metal nitride, a metal silicon nitride, a conductive metal oxide, a metal silicide, a noble metal, or a combination thereof. The lower electrode 101 may include at least one of titanium (Ti), titanium nitride (TiN), titanium silicon nitride (TiSiN), niobium nitride (NbN), tantalum (Ta), tantalum nitride (TaN), titanium aluminum nitride (TiAlN), tungsten (W), tungsten nitride (WN), ruthenium (Ru), ruthenium oxide (RuO2), iridium (Ir), iridium oxide (IrO2), platinum (Pt), molybdenum (Mo), molybdenum nitride (MoN), or a combination thereof. Additionally, the lower electrode 101 may include a silicon compound. The lower electrode 101 may include a silicon layer, a silicon germanium layer, or a combination thereof. Although FIG. 1 shows the lower electrode 101 in a flat shape, the shape of the lower electrode 101 is not limited thereto.

The interfacial layer 102 may be formed between the lower electrode 101 and the dielectric layer 103. The interfacial layer 102 can be formed by partially removing the lower electrode 101 using a wet cleaning etch, dry cleaning etch, or ALE (Atomic Layer Etch) process, or can be formed by a thin film that is changed from a metal nitride film to a metal oxide when the dielectric film is formed after removal. The metal oxide having a high work function can improve the electrical characteristics of the capacitor, such as leakage current and dielectric constant.

The interfacial layer 102 may include a metal oxide such as titanium oxide (Ti-oxide, TiOx), niobium oxide (Nb-oxide, NbOx), tantalum oxide (Ta-oxide, TaOx), molybdenum oxide (Mo-oxide, MoOx), or tungsten oxide (tungsten-oxide, WOx).

The dielectric layer 103 may include a metal oxide. The dielectric layer 103 may include aluminum oxide (Al2O3), titanium oxide (TiO2), hafnium oxide (HfO2), zirconium oxide (ZrO2), tantalum oxide (Ta2O5), or a combination thereof, but is not limited thereto.

The upper electrode 104 may include a metal nitride such as titanium nitride (TiN), niobium nitride (NbN), tantalum nitride (TaN), molybdenum nitride (MoN), tungsten nitride (WN), or a combination thereof, and may also include silicon-containing material. Although the upper electrode 104 is shown in a flat shape, the shape of the upper electrode 104 is not limited thereto.

As described above, according to an embodiment of the present invention, the capacitor can form a dielectric layer 103 having a larger dielectric constant by partially removing the lower electrode 101 and forming a metal oxide having a high work function, thereby forming a capacitor with improved electrical characteristics.

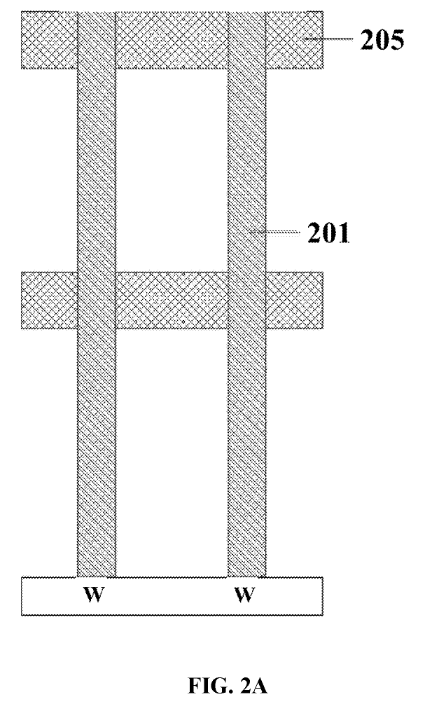

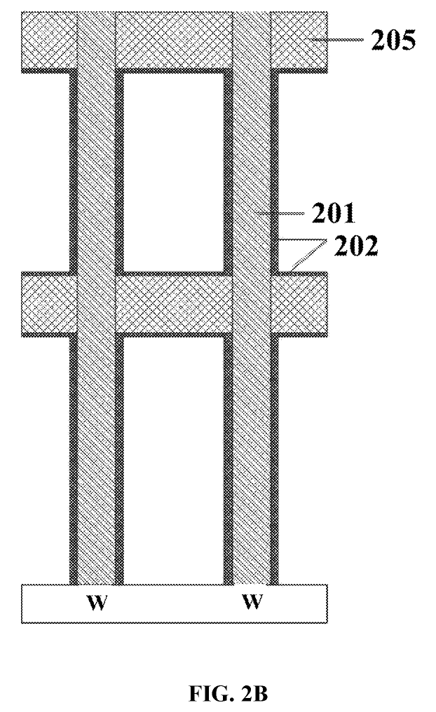

FIGS. 2A and 2B are views schematically showing a method of manufacturing a capacitor according to Comparative Example 1, showing a capacitor structure in which a lower electrode 201 and a supporter 205 are formed. As shown in FIG. 2A, the lower electrode 201 may have a pillar shape, and titanium nitride (TiN), which has low resistivity and high stability, is used. The supporter 205 may include silicon nitride (Si3N4) or silicon carbon nitride (SiCN), and may support the lower electrode 201 to prevent it from collapsing.

As shown in FIG. 2B, an interfacial layer 202 is deposited on the lower electrode 201 and facilitates crystallization of the dielectric film formed thereafter. When the interfacial layer 202 is deposited on the lower electrode 201, a crystal structure having a high dielectric constant can be formed at low temperatures during dielectric film formation. However, when the interfacial layer 202 is deposited on the supporter 205, leakage current increases. Therefore, a high selectivity interfacial layer 202 deposition process that deposits only on the lower electrode 201 without depositing on the supporter 205 is required.

Additionally, even with selective deposition of the interfacial layer 202, if some remains on the supporter 205, leakage current may increase. Therefore, a process capable of completely removing the interfacial layer 202 remaining on the supporter 205 is needed. Such selective interfacial layer 202 deposition or removal process delays the overall capacitor manufacturing process, decreasing UPH (units per hour), which is problematic.

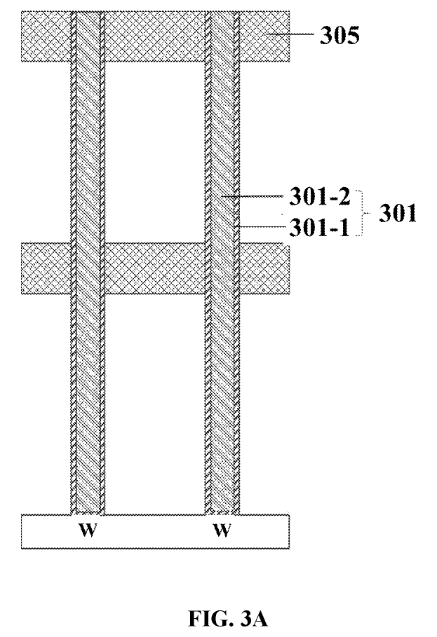

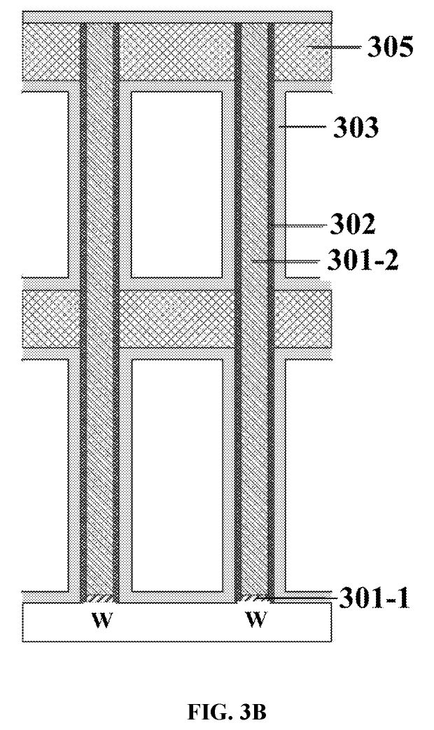

FIGS. 3A and 3B are views schematically showing a method of manufacturing a capacitor according to Comparative Example 2, showing a capacitor structure in which the lower electrode 301 has a composite structure including a first electrode layer 301-1 and a second electrode layer 301-2.

The first electrode layer 301-1 uses a metal nitride such as niobium nitride (NbN) with a high work function, and the second electrode layer 301-2 may use titanium nitride (TiN) or the like with low resistivity, and may be formed inside the first electrode layer 301-1.

As shown in FIG. 3B, when a dielectric film 303 is formed on the lower electrode 301, the first electrode layer 301-1 is oxidized to form an interfacial layer 302, and the interfacial layer 302 acts as an oxidation barrier so that the second electrode layer 301-2 is not oxidized.

The interfacial layer 302 facilitates crystallization of the dielectric film 303 and enables formation of a crystal structure with high dielectric constant. However, the first electrode layer 301-1 with high resistance still remains in contact with the lower contact plug (W, tungsten), which causes contact resistance to increase, resulting in degradation of the electrical characteristics of the capacitor.

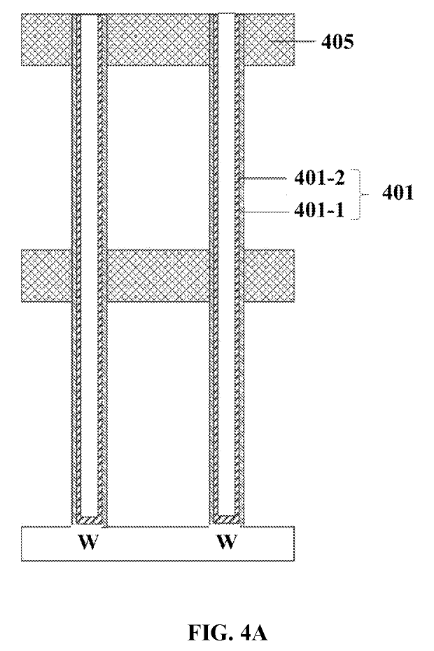

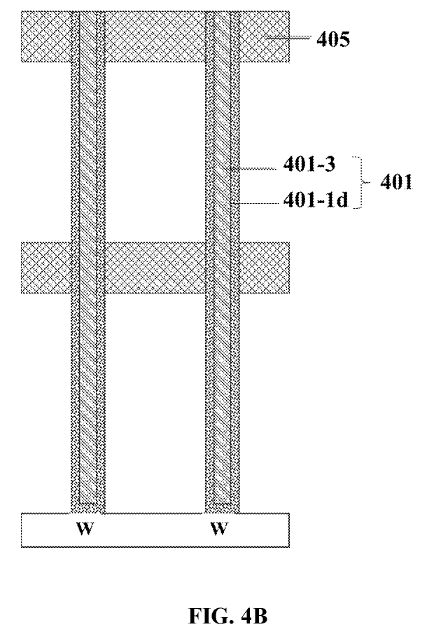

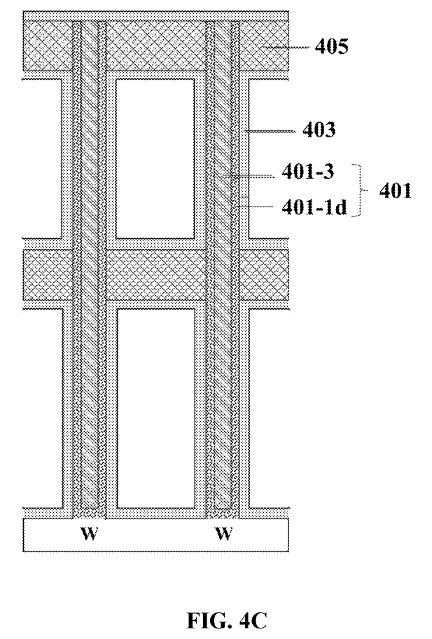

FIGS. 4A to 4C are views schematically showing a method of manufacturing a capacitor according to Comparative Example 3, showing a capacitor structure in which the lower electrode 401 has a composite structure including a first electrode layer 401-1 and a second electrode layer 401-2.

The first electrode layer 401-1 uses a metal nitride such as titanium nitride (TiN) with low resistivity, and the second electrode layer 401-2 uses a metal nitride such as niobium nitride (NbN), which can act as a dopant. The second electrode layer 401-2 may be formed inside the first electrode layer 401-1.

As shown in FIG. 4B, a doping region 401-1d can be formed by moving the dopant present in the second electrode layer 401-2 into the first electrode layer 401-1. For example, by raising the temperature of the first electrode layer 401-1 and the second electrode layer 401-2, the dopant in the second electrode layer 401-2 diffuses into the first electrode layer 401-1, forming a doping region 401-1d. After forming the doping region 401-1d, the second electrode layer 401-2 can be removed, and a third electrode layer 401-3 can be further deposited inside the doping region 401-1d to form the lower electrode 401. The third electrode layer 401-3 uses a metal nitride such as titanium nitride (TiN) with low resistivity and may include silicon-containing material.

As shown in FIG. 4C, when a dielectric film 403 is formed on the lower electrode 401 with the doping region 401-1d formed, the doping region 401-1d has lower resistivity compared to niobium nitride (NbN) and is in contact with the lower contact plug (W, tungsten), so contact resistance may not increase significantly. Additionally, it facilitates crystallization of the dielectric film 403 and can form a crystal structure with higher dielectric constant than when the doping region is not included. However, compared to directly depositing a material with high work function such as niobium oxide (Nb2O5) on the lower electrode 401, the effect is expected to be less. Therefore, to increase the dielectric constant further, a process capable of selectively depositing niobium oxide (Nb2O5) or the like only on the lower electrode 401 is required.

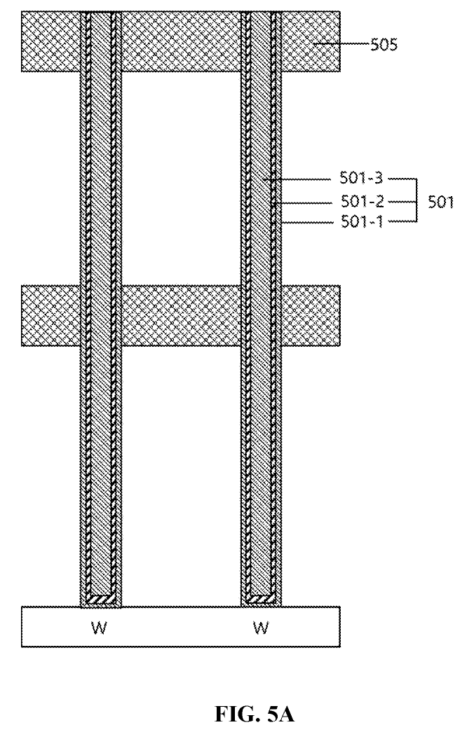

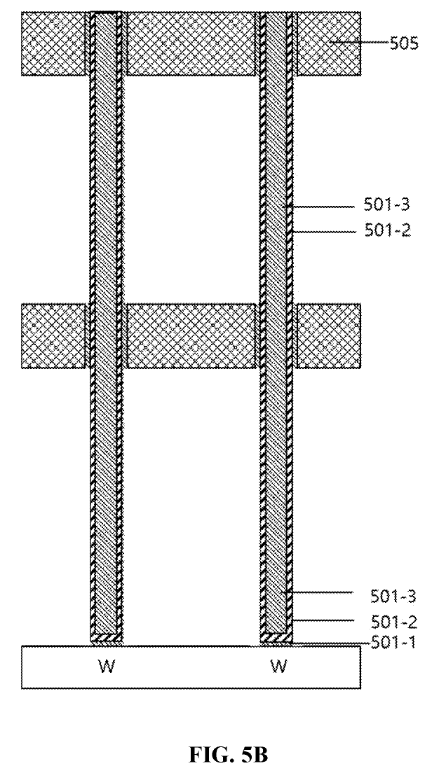

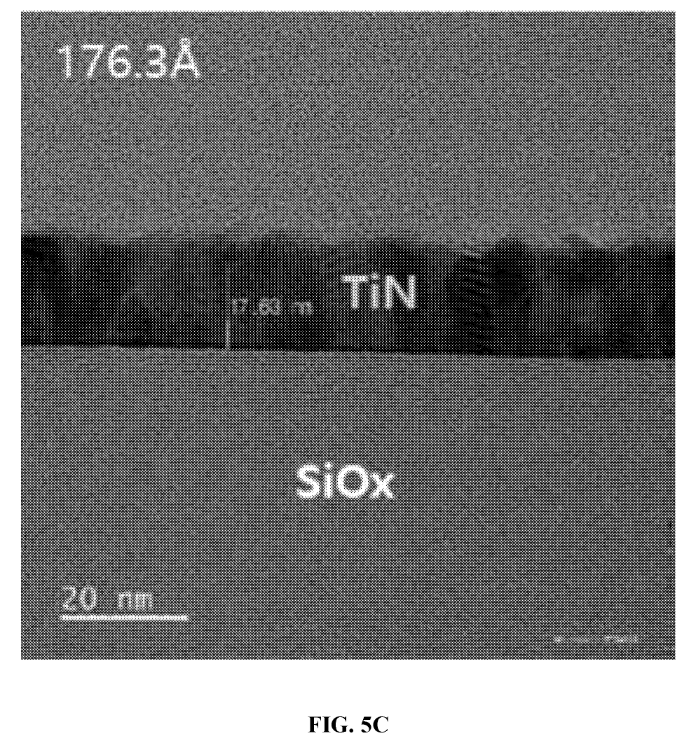

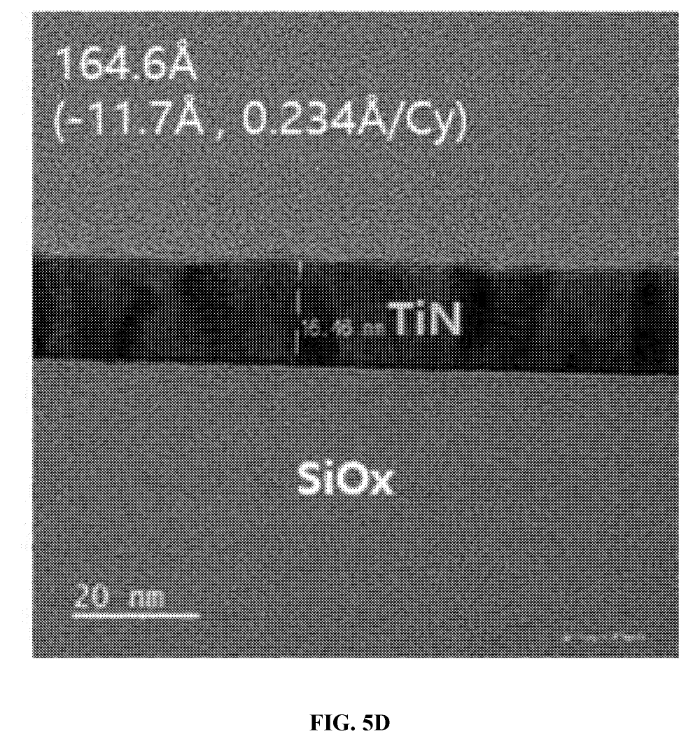

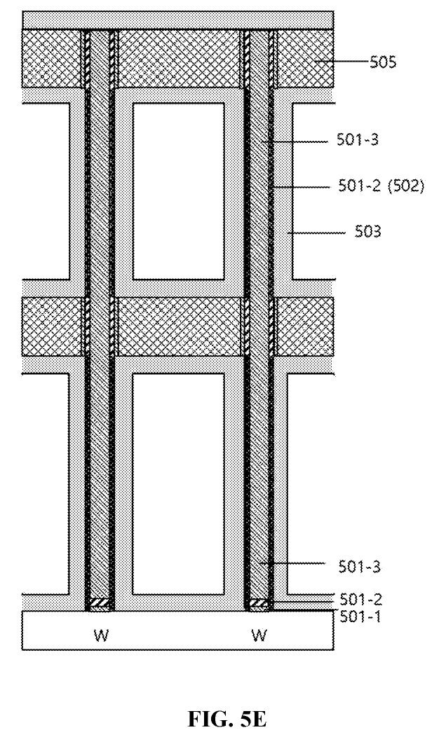

FIGS. 5A to 5E are views schematically showing a method of manufacturing a capacitor according to an embodiment of the present invention. A capacitor structure is shown in which the lower electrode 501 has a composite structure including a first electrode layer 501-1, a second electrode layer 501-2, and a third electrode layer 501-3, and the lower electrode 501 may have a pillar shape.

The bottom surface of the lower electrode 501 is in contact with a contact plug (W, tungsten), and the contact plug (W, tungsten) may penetrate through an insulating layer formed on a substrate to be connected to the substrate. The contact plug (W, tungsten) may be referred to as a storage node contact plug and may include a semiconductor material, a metal, a metal nitride, a metal silicide, or a combination thereof. Specifically, it may include polysilicon, tungsten, tungsten nitride, titanium nitride, titanium silicon nitride, titanium silicide, cobalt silicide, or a combination thereof. The lower electrode 501 may include silicon, a metal, a metal compound, or a combination thereof, but is not limited thereto.

The first electrode layer 501-1 may be at least one of a tetravalent metal nitride film including TiN, a pentavalent metal nitride film including NbN and TaN, a hexavalent metal nitride film including MoN and WN, and a tetravalent semi-metal nitride film including SiN and TiSiN. Specifically, it may include a metal nitride such as titanium nitride (TiN), niobium nitride (NbN), tantalum nitride (TaN), molybdenum nitride (MoN), tungsten nitride (WN), or a combination thereof, and may include silicon-containing material. The first electrode layer 501-1 may have a cylindrical shape.

The second electrode layer 501-2 is a material with high work function and may include at least one of a tetravalent metal nitride film including TiN, a pentavalent metal nitride film including NbN and TaN, and a hexavalent metal nitride film including MoN and WN. Specifically, it may include a metal nitride such as niobium nitride (NbN), tantalum nitride (TaN), molybdenum nitride (MoN), tungsten nitride (WN), and may have a cylindrical shape formed inside the first electrode layer 501-1.

The third electrode layer 501-3 may be at least one of a tetravalent metal nitride film including TiN, a pentavalent metal nitride film including NbN and TaN, a hexavalent metal nitride film including MoN and WN, and a tetravalent semi-metal nitride film including SiN and TiSiN. Specifically, it may include a metal nitride such as titanium nitride (TiN), niobium nitride (NbN), tantalum nitride (TaN), molybdenum nitride (MoN), tungsten nitride (WN), or a combination thereof, and may include silicon-containing material. The third electrode layer 501-3 may have a cylindrical shape formed inside the second electrode layer 501-2.

The supporter 505 may include a plate-like structure that extends horizontally to support outer walls of neighboring lower electrodes 501. The supporter 505 may include silicon nitride (Si3N4) or silicon carbon nitride (SiCN), and may support the lower electrode 501 to prevent it from collapsing.

As shown in FIG. 5B, after forming the lower electrode 501 including the first electrode layer 501-1, the second electrode layer 501-2, and the third electrode layer 501-3, the first electrode layer 501-1 corresponding to the sidewall of the lower electrode 501 can be removed. The first electrode layer 501-1 can be removed by methods such as wet cleaning etch, dry cleaning etch, or ALE (Atomic Layer Etch) process, as described below with reference to FIGS. 5C and 5D.

FIG. 5C is a TEM analysis result for a TiN wafer used as the first electrode layer 501-1, and FIG. 5D is a TEM analysis result after an ALE (Atomic Layer Etch) process is performed on the TiN wafer shown in FIG. 5C.

As shown in FIG. 5D, it was confirmed that 11.7 Å TiN thin film was removed after the ALE process. When the ALE process is performed, EPC (Etch Per Cycle) is approximately 0.23 Å/cycle, and the desired TiN thickness can be controlled and removed by adjusting the number of ALE cycles. The ALE process is one example of removing TiN, and the removal method is not limited thereto.

In conclusion, the first electrode layer 501-1 located on the sidewall of the lower electrode 501 can be removed to expose the second electrode layer 501-2, and the lower electrode 501 having a composite structure including the second electrode layer 501-2 and the third electrode layer 501-3 can be formed.

The exposed second electrode layer 501-2 is a material with high work function and can facilitate crystallization of the dielectric film during subsequent dielectric film deposition, helping to form a crystal structure with high dielectric constant. On the other hand, the lower electrode 501 in contact with the lower contact plug (W, tungsten) can have a composite structure including the first electrode layer 501-1, the second electrode layer 501-2, and the third electrode layer 501-3, with the first electrode layer 501-1 having low resistance in contact with the lower contact plug (W, tungsten), so contact resistance of the lower contact plug (W, tungsten) does not increase, and a lower electrode 501 structure that improves interfacial characteristics of the sidewall can be formed.

As shown in FIG. 5E, after removing only the first electrode layer 501-1 located on the sidewall of the lower electrode 501, a dielectric film 503 can be deposited, and the dielectric film 503 can be formed on the lower electrode 501 and the supporter 505. The dielectric film 503 may include a trivalent metal oxide film including Al2O3, a tetravalent metal oxide film including ZrO2 and HfO2, a pentavalent metal oxide film including Ta2O5, or a combination thereof.

The second electrode layer 501-2 can be changed from a metal nitride film to a metal oxide to form an interfacial layer 502 by oxidation during the removal of the first electrode layer 501-1 or during dielectric film deposition. However, although FIG. 5E shows the second electrode layer 501-2 being completely oxidized to form the interfacial layer 502, alternatively, only a portion of the second electrode layer 501-2 may be oxidized to form the interfacial layer 502, and the remaining portion may remain inside the interfacial layer 502. That is, the second electrode layer 501-2 and the interfacial layer 502 may coexist.

The interfacial layer 502 having high work function facilitates crystallization during dielectric film deposition to form a crystal structure with high dielectric constant, enabling formation of a high dielectric constant thin film. It also acts as an oxidation barrier to prevent oxidation of the lower electrode 501, preventing an increase in leakage current due to oxidation of the lower electrode.

The interfacial layer 502 may include a metal oxide such as titanium oxide (Ti-oxide, TiOx), niobium oxide (Nb-oxide, NbOx), tantalum oxide (Ta-oxide, TaOx), molybdenum oxide (Mo-oxide, MoOx), or tungsten oxide (tungsten-oxide, WOx), but is not limited thereto.

Thereafter, an upper electrode can be formed on the dielectric film 503. The upper electrode can fill the space between neighboring lower electrodes 501. The upper electrode may include a metal nitride such as titanium nitride (TiN), niobium nitride (NbN), tantalum nitride (TaN), molybdenum nitride (MoN), tungsten nitride (WN), or a combination thereof, and may also include silicon-containing material.

Based on the above description, a high dielectric constant capacitor thin film can be formed. Compared to Comparative Example 1, since the interfacial layer 502 is not formed on the supporter 505, the selective interfacial layer 502 formation and removal process is not required, thereby shortening the overall capacitor manufacturing process.

Additionally, compared to Comparative Example 2, because the structure has TiN with low resistance in contact with the lower W interface, the contact resistance of W does not increase, and a structure that improves interfacial characteristics of the sidewall can be formed.

Finally, compared to Comparative Example 3, a high work function material can be directly formed on the lower electrode to help form a crystal structure with high dielectric constant, and because the dielectric film can be deposited thicker by the thickness of the removed first electrode layer 501-1, formation of a high-k thin film is expected to be achievable.

Although the present invention has been described in detail through the above embodiments, other forms of embodiments are possible. Therefore, the technical spirit and scope of the claims set forth hereinafter are not limited to the embodiments.

What is claimed is:

1. A capacitor comprising:
a contact plug on a substrate;
a lower electrode on the contact plug;
a supporter supporting an outer wall of the lower electrode;
a dielectric layer on the lower electrode;
an upper electrode on the dielectric layer; and
an interfacial layer between the lower electrode and the dielectric layer,
wherein the lower electrode includes first to third electrode layers sequentially stacked within the supporter and above the contact plug.

2. The capacitor of claim 1, wherein the lower electrode further includes second and third electrode layers sequentially stacked on the outer wall within the interfacial layer.

3. The capacitor of claim 1, wherein the first and third electrode layers include at least one of a tetravalent metal nitride film including TiN, a pentavalent metal nitride film including NbN and TaN, a hexavalent metal nitride film including MoN and WN, and a tetravalent semi-metal nitride film including SiN and TiSiN, and wherein the second electrode layer has a higher work function than the first electrode layer.

4. The capacitor of claim 1, wherein the second electrode layer includes at least one of a tetravalent metal nitride film including TiN, a pentavalent metal nitride film including NbN and TaN, and a hexavalent metal nitride film including MoN and WN.

5. A method of manufacturing a capacitor for a semiconductor device, the method comprising:
forming a lower electrode positioned on a contact plug and a supporter supporting an outer wall of the lower electrode, the lower electrode having a first electrode layer, a second electrode layer formed inside the first electrode layer, and a third electrode layer formed inside the second electrode layer;
removing the first electrode layer located on an exposed sidewall of the lower electrode;
forming a dielectric film on an outer surface of the lower electrode; and
forming an upper electrode on the dielectric film.

6. The method of claim 5, wherein the first and third electrode layers include at least one of a tetravalent metal nitride film including TiN, a pentavalent metal nitride film including NbN and TaN, a hexavalent metal nitride film including MoN and WN, and a tetravalent semi-metal nitride film including SiN and TiSiN.

7. The method of claim 5, wherein the second electrode layer has a higher work function than the first electrode layer.

8. The method of claim 5, wherein the second electrode layer includes at least one of a tetravalent metal nitride film including TiN, a pentavalent metal nitride film including NbN and TaN, and a hexavalent metal nitride film including MoN and WN.

9. The method of claim 5, wherein the step of removing the first electrode layer is performed by a wet cleaning etch, a dry cleaning etch, or an ALE (Atomic Layer Etch) process.

10. The method of claim 5, wherein the step of removing the first electrode layer comprises:
removing the first electrode layer on the outer wall of the lower electrode to expose the second electrode layer; and
leaving the first electrode layer inside the supporter and adjacent to the contact plug.

11. The method of claim 5, wherein the dielectric film includes at least one of a trivalent metal oxide film including Al2O3, a tetravalent metal oxide film including ZrO2 and HfO2, and a pentavalent metal oxide film including Ta2O5.

12. The method of claim 5, wherein the step of forming the dielectric film comprises:
oxidizing the second electrode layer located on the exposed sidewall of the lower electrode to form an interfacial layer.

13. The method of claim 5, wherein the step of removing the first electrode layer comprises:
oxidizing the second electrode layer located on the exposed sidewall of the lower electrode to form an interfacial layer.

14. The method of claim 12, wherein the step of forming the interfacial layer comprises:
leaving the second electrode layer located inside the supporter and on top of the contact plug.

15. The method of claim 12, wherein the interfacial layer includes at least one of titanium oxide (TiOx), niobium oxide (NbOx), tantalum oxide (TaOx), molybdenum oxide (MoOx), and tungsten oxide (WOx).

16. A method of manufacturing a memory device, including the method of manufacturing a capacitor according to claim 5.

17. The capacitor of claim 2, wherein the first and third electrode layers include at least one of a tetravalent metal nitride film including TiN, a pentavalent metal nitride film including NbN and TaN, a hexavalent metal nitride film including MoN and WN, and a tetravalent semi-metal nitride film including SiN and TiSiN, and wherein the second electrode layer has a higher work function than the first electrode layer.

18. The capacitor of claim 2, wherein the second electrode layer includes at least one of a tetravalent metal nitride film including TiN, a pentavalent metal nitride film including NbN and TaN, and a hexavalent metal nitride film including MoN and WN.

19. The method of claim 13, wherein the step of forming the interfacial layer comprises:
leaving the second electrode layer located inside the supporter and on top of the contact plug.

20. The method of claim 13, wherein the interfacial layer includes at least one of titanium
oxide (TiOx), niobium oxide (NbOx), tantalum oxide (TaOx), molybdenum oxide (MoOx), and tungsten oxide (WOx).
